(19) United States
(12) Patent Application Publication
(10) Pub. No.: US 2015/0114828 A1
(43) Pub. Date: Apr. 30, 2015

(54) SYSTEMS AND METHOD OF COATING AN INTERIOR SURFACE OF AN OBJECT

(71) Applicant: General Electric Company, Schenectady, NY (US)

(72) Inventor: Scott Andrew Weaver, Ballston Lake, NY (US)

(73) Assignee: General Electric Company, Schenectady, NY (US)

(21) Appl. No.: 14/068,436

(22) Filed: Oct. 31, 2013

(51) Int. Cl. C23C 14/32

(52) U.S. Cl. CPC C23C 14/325
USPC 204/192.38; 204/298.41

(57) ABSTRACT

A system for use in coating an interior surface of an object is provided. The system includes a vacuum chamber enclosure defining an interior cavity configured to receive the object, an anode positioned within the interior cavity of the vacuum chamber enclosure, and a cathode positioned within the interior cavity of said vacuum chamber enclosure such that a space between the anode and the cathode is at least partially defined by the interior surface of the object. At least a portion of the cathode vaporizes when current is supplied thereto such that vaporized cathode material coats the interior surface of the object.

### BACKGROUND

The present disclosure relates generally to physical vapor deposition and, more specifically, to a system and methods for applying a coating directly to an interior surface of an object via cathodic arc deposition.

At least some known physical vapor deposition processes vaporize and deposit a target material onto surfaces of a workpiece to form a coating thereon. For example, in physical vapor deposition processes such as cathodic arc deposition, current is supplied to, and an electric arc is struck on a face of a target cathode to vaporize the target material from the face of the cathode. The vaporization of the cathode forms a cloud of highly ionized material that substantially fills an interior of a vacuum chamber. The coating is then formed on the workpiece by allowing the cloud to contact exposed surfaces thereof

Generally, vaporization of a cathode in a vacuum environment forms a substantially uniform coating on the exposed surfaces of the workpiece. More specifically, at least some of the surfaces of the workpiece may be shielded such that only the exposed surfaces receive a coating thereon. However, the cloud of coating material will also deposit on an interior surface of the vacuum chamber. Moreover, cathodic arc deposition is a line-of-sight process such that only surfaces exposed to the cloud of coating material receive a coating thereon. As such, it is difficult to ensure that the coating material deposits on hard-to-reach surfaces of a workpiece, such as an interior surface thereof

### BRIEF DESCRIPTION

In one aspect, a system for use in coating an interior surface of an object is provided. The system includes a vacuum chamber enclosure defining an interior cavity configured to receive the object, an anode positioned within the interior cavity of the vacuum chamber enclosure, and a cathode positioned within the interior cavity of said vacuum chamber enclosure such that a space between the anode and the cathode is at least partially defined by the interior surface of the object. At least a portion of the cathode vaporizes when current is supplied thereto such that vaporized cathode material coats the interior surface of the object.

In another aspect, a method of coating an interior surface of an object is provided. The method includes providing a vacuum chamber enclosure defining an interior cavity configured to receive the object, positioning the object within the interior cavity of the vacuum chamber enclosure, positioning an anode within the interior cavity of the vacuum chamber enclosure, positioning a cathode within the interior cavity of the vacuum chamber enclosure such that a space between the anode and the cathode is at least partially defined by the interior surface of the object, and supplying current to the cathode to vaporize at least a portion of the cathode, wherein vaporized cathode material coats the interior surface of the object.

### DRAWINGS

These and other features, aspects, and advantages of the present disclosure will become better understood when the following detailed description is read with reference to the accompanying drawings in which like characters represent like parts throughout the drawings, wherein:

FIG. 1 is a schematic illustration of an exemplary physical vapor deposition system;

FIG. 2 is an enlarged sectional illustration of the physical vapor deposition system shown in FIG. 1; and

FIG. 3 is a flow diagram of an exemplary method of coating an interior surface of an object.

Unless otherwise indicated, the drawings provided herein are meant to illustrate features of embodiments of the disclosure. These features are believed to be applicable in a wide variety of systems comprising one or more embodiments of the disclosure. As such, the drawings are not meant to include all conventional features known by those of ordinary skill in the art to be required for the practice of the embodiments disclosed herein.

### DETAILED DESCRIPTION

In the following specification and the claims, reference will be made to a number of terms, which shall be defined to have the following meanings.

The singular forms “a”, “an”, and “the” include plural references unless the context clearly dictates otherwise.

“Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

Embodiments of the present disclosure relate to systems and methods that are used to apply a coating directly to an interior surface of an object. More specifically, the interior surface of the object is coated via physical vapor deposition. In the exemplary embodiment, a vacuum chamber enclosure is provided and the object is positioned within the vacuum chamber enclosure. An anode and a cathode are also positioned within the vacuum chamber enclosure such that a space between the anode and the cathode is at least partially defined by the interior surface of the object. As such, when current is supplied to the cathode, the cathode material vaporizes and coats the interior surface in the space between the anode and the cathode.

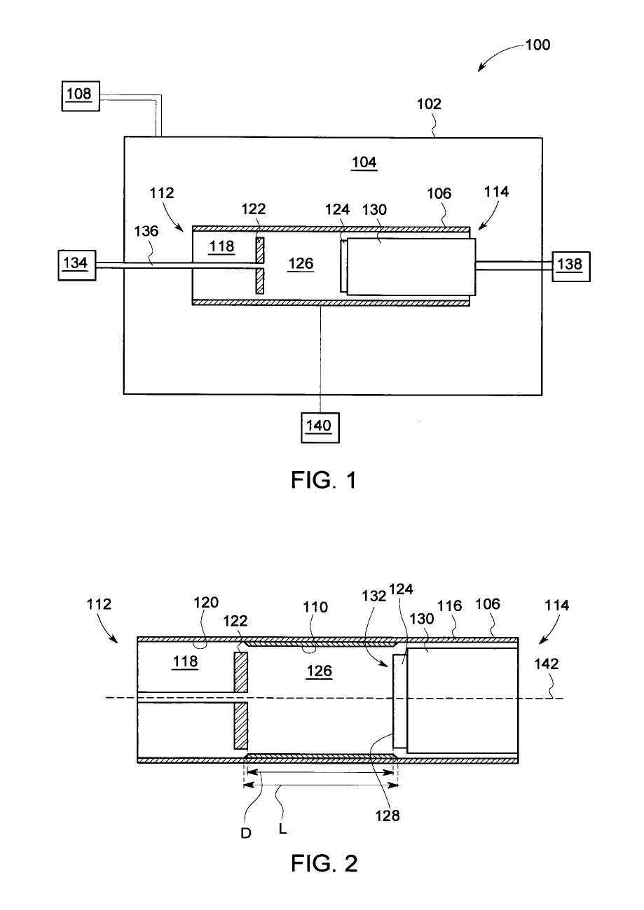

FIG. 1 is a schematic illustration of an exemplary physical vapor deposition system 100, and FIG. 2 is an enlarged sectional illustration of physical vapor deposition system 100. In the exemplary embodiment, system 100 includes a vacuum chamber enclosure 102 defining an interior cavity 104 configured to receive an object 106 to be coated therein. Vacuum chamber enclosure 102 is coupled to a vacuum system 108 that facilitates creating a vacuum within vacuum chamber enclosure 102. In the exemplary embodiment, vacuum chamber enclosure 102 is evacuated to a pressure of between about 10⁻⁴ torr and about 10⁻⁵ torr during operation thereof In an alternative embodiment, vacuum chamber enclosure 102 operates at a partial pressure atmosphere of reactive gas.

Object 106 is positioned within interior cavity 104 of vacuum chamber enclosure 102 to enable a coating 110 to be deposited thereon. In the exemplary embodiment, object 106 has a substantially cylindrical shape and includes a first open end 112, a second open end 114, and a side wall 116 extending therebetween. Object 106 also includes an interior cavity 118 and an interior surface 120 of side wall 116. Alternatively, object 106 has any shape that enables system 100 to function as described herein.

In the exemplary embodiment, system 100 also includes an anode 122 and a cathode 124 positioned within interior cavity 104 of vacuum chamber enclosure 102. Anode 122 and cathode 124 are positioned such that a space 126 is defined therebetween. More specifically, anode 122 and cathode 124 are positioned at opposing ends of object 106 such that space 126 is at least partially defined by interior cavity 118 and interior surface 120 of object 106. For example, anode 122 is sized for insertion through first open end 112 and into interior cavity 118 of object 106 with a clearance fit, and/or cathode 124 is sized for insertion through second open end 114 and into interior cavity 118 of object 106 with a clearance fit. As such, the clearance facilitates limiting the formation of a short circuit between interior surface 120 and anode 122 and/or cathode 124 during operation. Alternatively, anode 122 and cathode 124 are positioned at opposing ends of object 106, but are not inserted into interior cavity 118.

Anode 122 is fabricated from any material that enables system 100 to function as described herein. More specifically, anode 122 is fabricated from material that facilitates sustaining electrical discharge on a face 128 of cathode 124. For example, the material used to fabricate anode 122 is selected based on the material used to fabricate cathode 124, and a desired coating 110 to be applied to interior surface 120 of object 106. Exemplary materials include, but are not limited to, a metallic alloy material, an intermetallic material, and/or an elemental metal.

Cathode 124 is fabricated from any material that enables system 100 to function as described herein. More specifically, cathode 124 is fabricated from a coating material to be deposited on interior surface 120 of object 106. Exemplary coating materials include, but are not limited to, a metallic alloy material, an intermetallic material, and/or an elemental metal. Alternatively, cathode 124 is fabricated from more than one coating material. Moreover, in the exemplary embodiment, an insulator 130 extends over at least a portion of cathode 124 to facilitate sustaining electrical discharge on face 128 of cathode 124. More specifically, insulator 130 extends over cathode 124 such that electrical discharge is restricted from traveling off face 128 and away from anode 122. Moreover, insulator 130 covers cathode 124 such that an exposed portion 132 of cathode 124 is adjacent to and remains substantially unobstructed from anode 122. As such, maintaining line-of-sight between anode 122 and exposed portion 132 facilitates sustaining electrical discharge on face 128 of cathode 124.

In the exemplary embodiment, system 100 also includes a reactive gas source 134, and a reactive gas supply tube 136 coupled between reactive gas source 134 and anode 122. More specifically, reactive gas supply tube 136 facilitates channeling reactive gas (not shown) from reactive gas source 134, through anode 122, and into interior cavity 118 of object 106 at space 126 between anode 122 and cathode 124. Exemplary reactive gas includes, but is not limited to, nitrogen. The reactive gas is configured to interact with vaporized coating material from cathode 124 to deposit coating 110 fabricated from the interacted materials on interior surface 120 of object 106. In an alternative embodiment, supply tube 136 directs reactive gas towards space 126 through the clearance defined between anode 122 and/or cathode 124 and interior surface 120.

In operation, a vacuum is drawn in interior cavity 104 of vacuum chamber enclosure 102, and a power supply 138 supplies current to cathode 124 to form a difference in electric potential between anode 122 and cathode 124. An electric arc (not shown) is struck on face 128 of cathode 124 by an igniter (not shown), and the current supplied to cathode 124 facilitates vaporizing the coating material to remove the coating material from cathode 124. Power supply 138 supplies any current that enables system 100 to function as described herein. For example, the amount of current supplied is selected based on the coating material used to fabricate cathode 124 and/or a desired rate of vaporization of the coating material. In the exemplary embodiment, the amount of current supplied to cathode 124 is selected to facilitate restricting molten coating material from being discharged towards interior surface 120. For example, the current supplied to cathode 124 may be high enough to vaporize the coating material, but low enough to facilitate reducing molten coating material discharge.

In some embodiments, system 100 includes a voltage supply 140 that supplies a voltage bias to object 106. More specifically, in operation, voltage supply 140 facilitates inducing a negative charge to object 106 such that positively charged ions are attracted to object 106. As such, inducing the negative charge to object 106 facilitates attracting the positively charged vaporized coating material towards interior surface 120 of object 106 to form coating 110 thereon.

As current is supplied to cathode 124, reactive gas is channeled through supply tube 136 and into space 126 defined between anode 122 and cathode 124. As described above, the reactive gas interacts with the vaporized coating material from cathode 124 to form coating 110 on interior surface 120 of object 106. More specifically, coating 110 is formed on interior surface 120 in space 126 defined between anode 122 and cathode 124. Length L of coating 110 on interior surface 120 is determined as a function of a distance D between anode 122 and cathode 124. Distance D is selected as a function of sustaining electrical discharge on face 128 of cathode 124. Moreover, in the exemplary embodiment, at least one of object 106, anode 122, and/or cathode 124 are translatable relative to each other to facilitate forming coating 110 at different axial locations along a longitudinal axis 142 of object 106 in space 126 defined between anode 122 and cathode 124. In an alternative embodiment, the reactive gas is not channeled towards space 126 such that coating 110 is only formed from vaporized cathode material.

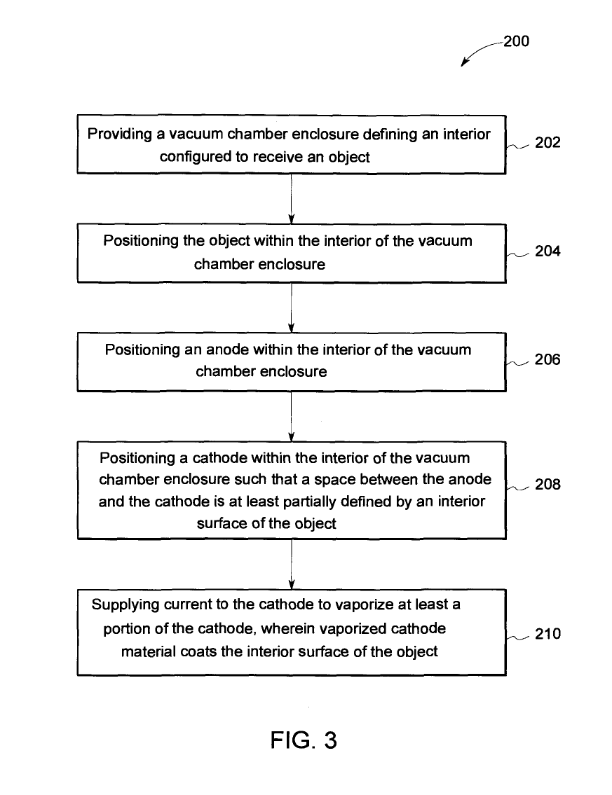

FIG. 3 is a flow diagram of an exemplary method 200 of coating an interior surface of an object, such as interior surface 120 of object 106 (shown in FIG. 1), is also provided herein. The method includes providing 202 a vacuum chamber enclosure defining an interior cavity configured to receive an object. The object is positioned 204 within the interior cavity of the vacuum chamber enclosure, an anode is positioned 206 within the interior cavity of the vacuum chamber enclosure, and a cathode is positioned 208 within the interior cavity of the vacuum chamber enclosure. The anode and the cathode are positioned 206 and 208 such that a space between the anode and the cathode is at least partially defined by the interior surface of the object. More specifically, the anode and cathode are positioned at opposing ends of the object such that the space is at least partially defined by the interior cavity of the object. Current is then supplied 210 to the cathode to vaporize material of the cathode. The vaporized material coats the interior surface of the object in the space between the anode and the cathode.

The systems and methods described herein enable coating of an interior surface of an object using a physical vapor deposition process. In the exemplary embodiments, the systems described herein include an anode and a cathode positioned at opposed ends of an object such that a space is defined therebetween. The space is also at least partially defined by an interior surface of the object. When current is supplied to the cathode, the cathode material vaporizes and coats the interior surface in the space defined between the anode and the cathode. As such, a portion of the interior surface to be coated is selected as a function of a location of the anode and/or the cathode along the object and the space defined therebetween.

An exemplary technical effect of the methods, systems, and assembly described herein includes at least one of (a) enabling a coating to be applied to hard-to-reach interior surfaces of an object; (b) reducing manufacturing costs by directing the coating material directly onto an interior surface of the object; and (c) reducing manufacturing time of coated objects by more efficiently coating interior surfaces of the objects.

Exemplary embodiments of the physical vapor deposition system are described above in detail. The system is not limited to the specific embodiments described herein, but rather, components of systems and/or steps of the methods may be utilized independently and separately from other components and/or steps described herein. For example, the system may also be used in combination with other physical vapor deposition processes, and are not limited to practice with only the physical vapor deposition process and methods as described herein. Rather, the exemplary embodiment can be implemented and utilized in connection with many applications where improving durability of an object with a coating is desirable.

Although specific features of various embodiments of the present disclosure may be shown in some drawings and not in others, this is for convenience only. In accordance with the principles of embodiments of the present disclosure, any feature of a drawing may be referenced and/or claimed in combination with any feature of any other drawing.

This written description uses examples to disclose the embodiments of the present disclosure, including the best mode, and also to enable any person skilled in the art to practice embodiments of the present disclosure, including making and using any devices or systems and performing any incorporated methods. The patentable scope of the embodiments described herein is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A system for use in coating an interior surface of an object, said system comprising:
a vacuum chamber enclosure defining an interior cavity configured to receive the object;
an anode positioned within said interior cavity of said vacuum chamber enclosure; and
a cathode positioned within said interior cavity of said vacuum chamber enclosure such that a space between said anode and said cathode is at least partially defined by the interior surface of the object, wherein at least a portion of said cathode vaporizes when current is supplied thereto such that vaporized cathode material coats the interior surface of the object.

2. The system in accordance with claim 1, wherein at least one of said anode and said cathode are sized for insertion through an open end of the object and into an interior cavity of the object.

3. The system in accordance with claim 2, wherein a clearance is defined between the interior surface of the object and said at least one of said anode and said cathode when positioned in the interior cavity of the object.

4. The system in accordance with claim 1 further comprising an insulator extending over at least a portion of said cathode and configured to sustain electrical discharge on a face of said cathode when current is supplied to said cathode.

5. The system in accordance with claim 4, wherein said insulator defines an exposed portion of said cathode, said insulator extending over said cathode such that said exposed portion is adjacent to said anode.

6. The system in accordance with claim 1 further comprising a gas supply tube configured to channel reactive gas to the interior cavity of the object.

7. The system in accordance with claim 6, wherein the reactive gas comprises nitrogen.

8. The system in accordance with claim 1, wherein the object includes a longitudinal axis extending along a length thereof, wherein at least one of said anode and said cathode are configured to translate along the longitudinal axis.

9. The system in accordance with claim 1 further comprising a voltage supply coupled to the object, wherein said voltage supply is configured to supply a voltage bias to the object.

10. The system in accordance with claim 1, wherein the interior cavity of the vacuum chamber enclosure is evacuated to a pressure between about 10⁻⁴ torr and about 10⁻⁵ torr.

11. A method of coating an interior surface of an object, said method comprising:
providing a vacuum chamber enclosure defining an interior cavity configured to receive the object;
positioning the object within the interior cavity of the vacuum chamber enclosure;
positioning an anode within the interior cavity of the vacuum chamber enclosure;
positioning a cathode within the interior cavity of the vacuum chamber enclosure such that a space between the anode and the cathode is at least partially defined by the interior surface of the object; and
supplying current to the cathode to vaporize at least a portion of the cathode, wherein vaporized cathode material coats the interior surface of the object.

12. The method in accordance with claim 11 further comprising selecting a portion of the interior surface to be coated as a function of a location of at least one of the anode and the cathode.

13. The method in accordance with claim 11 further comprising translating at least one of the anode and the cathode relative to the object to coat the interior surface at different axial locations along a longitudinal axis of the object.

14. The method in accordance with claim 11 further comprising channeling reactive gas towards the interior cavity of the object to react with the vaporized cathode material.

15. The method in accordance with claim 14, wherein channeling reactive gas comprises channeling the reactive gas towards the space between the anode and the cathode.

16. The method in accordance with claim 11 further comprising sizing at least one of the anode and the cathode for insertion through an open end of the object and into an interior cavity of the object.

17. The method in accordance with claim 16, wherein sizing at least one of the anode and the cathode comprises defining a clearance between the interior surface of the object and at least one of the anode and the cathode when positioned in the interior cavity of the object.

18. The method in accordance with claim 11 further comprising supplying a voltage bias to the object to facilitate attracting the vaporized cathode material towards the interior surface of the object.

19. The method in accordance with claim 11, wherein supplying current to the cathode comprises selecting an amount of current to supply that facilitates restricting molten coating material from being discharged towards the interior surface.

20. The method in accordance with claim 11 further comprising extending an insulator over at least a portion of the cathode to facilitate sustaining electrical discharge on a face of the cathode when current is supplied to the cathode.
